(19) United States
(12) Patent Application Publication
(10) Pub. No.: US 2017/0040377 A1
(43) Pub. Date: Feb. 9, 2017

(54) SENSING DEVICE

(71) Applicant: KABUSHIKI KAISHA TOSHIBA, Minato-ku (JP)

(72) Inventors: Keiji IKEDA, Kawasaki (JP); Tsutomu TEZUKA, Tsukuba (JP)

(73) Assignee: KABUSHIKI KAISHA TOSHIBA, Minato-ku (JP)

(21) Appl. No.: 15/226,276

(22) Filed: Aug. 2, 2016

(30) Foreign Application Priority Data
Aug. 4, 2015 (JP) 2015-154128

(51) Int. Cl. H01L 27/146

(52) U.S. Cl. CPC H01L 27/14643; H01L 27/14612; H01L 27/14609; H01L 27/14636

(57) ABSTRACT

According to one embodiment, a sensing device includes a photodiode; a first transistor including a first terminal, a second terminal and a control terminal, the first terminal being connected to the photodiode; an electrode configured to detect a potential of the measurement target; a second transistor including a third terminal, a fourth terminal and a control terminal, the third terminal being connected to the electrode; and a charge storage connected to the second terminal of the first transistor and to the fourth terminal of the second transistor.

### CROSS-REFERENCE TO RELATED APPLICATIONS

This application is based upon and claims the benefit of priority from the prior Japanese Patent Application No. 2015-154128, filed Aug. 4, 2015, the entire contents of which are incorporated herein by reference.

### FIELD

Embodiments described herein relate generally to a sensing device.

### BACKGROUND

A pluripotent stem cell, such as an iPS cell, can differentiate into cells of various tissues or cells of organs by proliferation by culture, and by functionalization by differentiation. Thus, the development of culture/differentiation control technologies of stem cells are expected for the screening of candidate substances at a time of drug development, and for the transplant of various tissues and organs in the field of regenerative medicine.

On the other hand, the security of safety and the cost reduction of stem cells are challenges to be addressed in popularizing drug development and regenerative medicine. For example, in stem cell culture, tumorigenic transformation may occur. Thus, there is a strong demand for the establishment of methods of establishing and screening only safe stem cells, and for the development of cell culture techniques and cell test techniques with high general-purpose applicability at low cost.

As an example of the cell test technique, in a drug development test, the use of a cell potential observation sensor array has been studied. In the drug development test, cells are directly cultured on a SiN passivation layer of the cell potential observation sensor array. The SiN passivation layer includes opening portions in a manner to expose electrode portions which are arranged in an array (matrix). In the drug development test, a potential variation of a cell is sensed by capacitive coupling between the cell and electrode, thereby realizing intercellular potential propagation observation. The potential of the cell varies due to propagation of a neurotransmitter if the cell is a nerve cell, or due to transmission/reception of ions via ion channels existing in a cell membrane if the cell is some other kind of cell.

In this method, there is a demand for observing not only the potential variation of the cell, but also an optical image of the cell. In order to achieve this, there has been proposed a configuration in which the above-described electrode is disposed above a photodiode. Furthermore, in order to enhance the resolution of potential observation, it is required to decrease the electrode size and to increase the number of electrodes.

However, if the number of electrodes increases, the number of wirings, which are connected in order to select the electrodes, will also increase. To be more specific, one wiring in a row and one wiring in a column are needed for one electrode. In other words, since a plurality of electrodes are disposed in a matrix, a plurality of wirings are disposed for one row, and a plurality of wirings are disposed for one column. Consequently, due to light-shielding by the wirings, incident light on photodiodes, which are located in a lower layer, becomes deficient, and the sensitivity of optical images by the photodiodes lowers. As a result, the number of electrodes cannot be increased, and it is difficult to enhance the resolution of potential observation.

### BRIEF DESCRIPTION OF THE DRAWING

FIG. 1 is a block diagram illustrating the entire configuration of a sensing device according to a first embodiment;

FIG. 2 is a plan view illustrating a layout of a pixel array of the sensing device according to the first embodiment, FIG. 2 illustrating, in particular, photodiodes on a substrate surface;

FIG. 3 is a plan view illustrating the layout of the pixel array of the sensing device according to the first embodiment, FIG. 3 illustrating, in particular, electrodes above the substrate;

FIG. 4 is a cross-sectional view taken along line A-A in FIG. 3, FIG. 4 illustrating a pixel unit of the sensing device according to the first embodiment;

FIG. 5 is a block diagram illustrating an electrical connection relation of the pixel unit according to the first embodiment;

FIG. 6 is a circuit diagram illustrating, in greater detail, the electrical connection relation of the pixel unit in the sensing device according to the first embodiment;

FIG. 7 is a timing chart illustrating voltages of respective signal lines in the sensing device according to the first embodiment;

FIG. 8 is a cross-sectional view illustrating a pixel unit of a sensing device according to a second embodiment;

FIG. 9 is a block diagram illustrating an electrical connection relation of the pixel unit according to the second embodiment;

FIG. 10 is a circuit diagram illustrating, in greater detail, the electrical connection relation of the pixel unit in the sensing device according to the second embodiment;

FIG. 11 is a block diagram illustrating an electrical connection relation of a pixel unit according to a modification of the second embodiment;

FIG. 12 is a circuit diagram illustrating, in greater detail, the electrical connection relation of the pixel unit in the sensing device according to the modification of the second embodiment;

FIG. 13 is a block diagram illustrating the entire configuration of a sensing device according to a third embodiment;

FIG. 14 is a cross-sectional view illustrating a pixel unit of the sensing device according to the third embodiment;

FIG. 15 is a block diagram illustrating an electrical connection relation of the pixel unit according to the third embodiment; and

FIG. 16 is a circuit diagram illustrating, in greater detail, the electrical connection relation of the pixel unit in the sensing device according to the third embodiment.

### DETAILED DESCRIPTION

In general, according to one embodiment, a sensing device includes a photodiode; a first transistor including a first terminal, a second terminal and a control terminal, the first terminal being connected to the photodiode; an electrode configured to detect a potential of the measurement target; a second transistor including a third terminal, a fourth terminal and a control terminal, the third terminal being connected to the electrode; and a charge storage connected to the second terminal of the first transistor and to the fourth terminal of the second transistor.

Various embodiments will be described hereinafter with reference to the accompanying drawings. In the drawings, the same parts are denoted by like reference numerals.

### First Embodiment

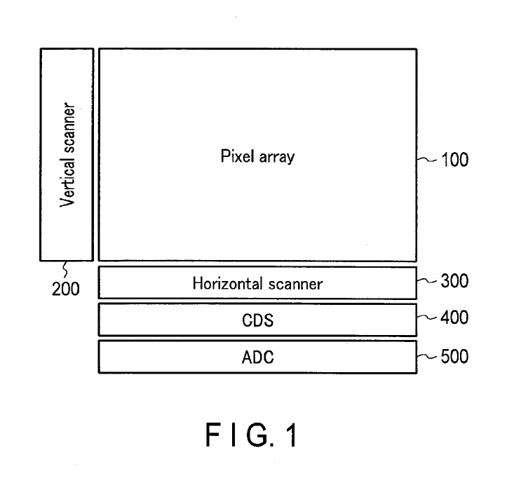

Referring to FIGS. 1, 2, 3, 4, 5, 6, and 7, a sensing device according to a first embodiment will be described below.

In the first embodiment, a pixel unit 110 includes photodiodes PD disposed on a semiconductor substrate 11, and an electrode ME disposed above the photodiodes PD. The electrode ME is connected to a floating diffusion FD via a transfer transistor TGM, and the photodiodes PD are connected to the floating diffusion FD via transfer transistors TGP. Thereby, a potential and an optical image of a biotissue can be observed at the same time, and it is possible to enhance the sensitivity of an optical image by the photodiodes PD and the resolution of potential observation.

The first embodiment will be described below in detail.

### Configuration and Operation in the First Embodiment

FIG. 1 is a block diagram illustrating the entire configuration of the sensing device according to the first embodiment.

As illustrated in FIG. 1, the sensing device includes a pixel array 100, a vertical scanner 200, a horizontal scanner 300, a CDS (correlated double sampler) 400, and an ADC (analog-to-digital converter) 500.

The pixel array 100 is composed of a plurality of pixel units 110 which are arranged in an array (matrix) in a horizontal direction (row direction) and a vertical direction (column direction). Each pixel unit 110 generates an optical signal, and detects a potential signal. The optical signal is generated in accordance with the amount of light from the side of a measurement target such as a biotissue, and the potential signal is detected in accordance with a potential variation of the biotissue. The vertical scanner 200 selects a row of pixel units 110, and the horizontal scanner 300 selects a column of pixel units 110. The optical signal and potential signal of a selected pixel unit 110 are converted to digital data via the CDS 400 and ADC 500.

Although a description is given below of an example in which a cell (biological cell, stem cell) is observed as a biotissue, the target of observation is not limited to the cell. DNA, RNA, peptide, saccharides, etc. may be observed.

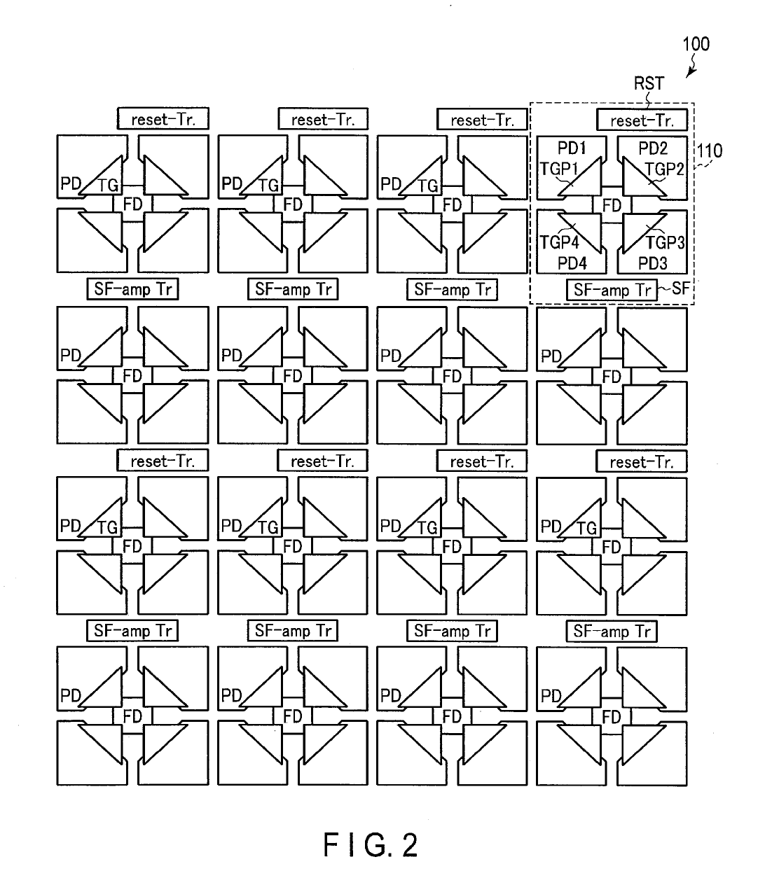

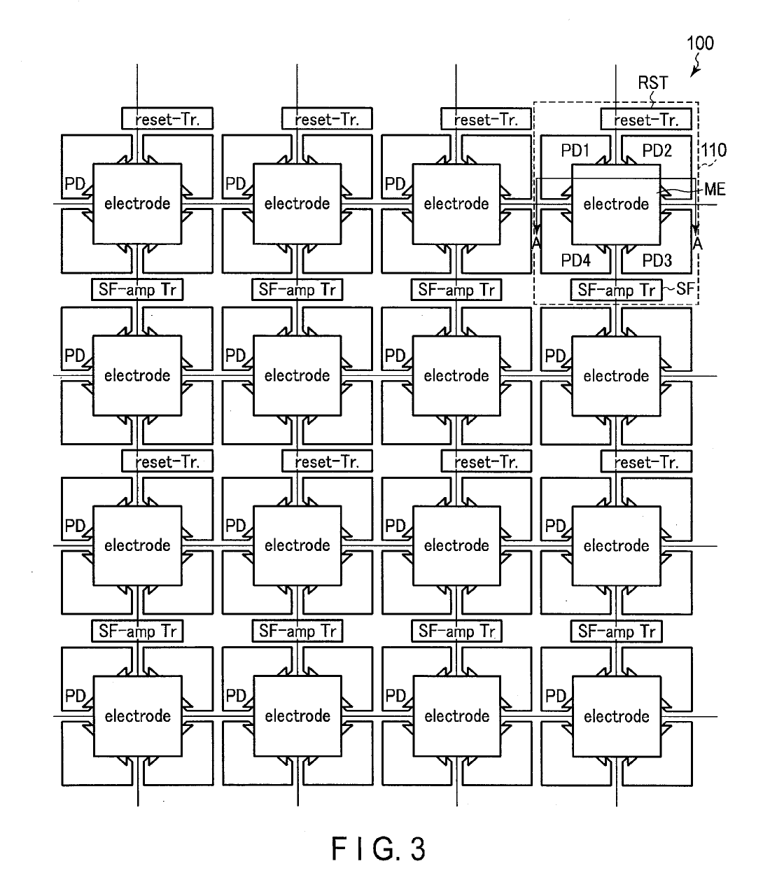

FIG. 2 is a plan view illustrating a layout of the pixel array 100 of the sensing device according to the first embodiment, FIG. 2 illustrating, in particular, photodiodes PD on a substrate surface. FIG. 3 is a plan view illustrating the layout of the pixel array 100 of the sensing device according to the first embodiment, FIG. 3 illustrating, in particular, electrodes ME above the substrate.

As illustrated in FIG. 2, the pixel array 100 includes a plurality of pixel units 110 arranged in a matrix. The pixel unit 110 includes four photodiodes PD1 to PD4, four transfer transistors TGP0 to TGP4, a floating diffusion (charge storage) FD, a reset transistor RST, and a source follower amplifier (source follower amplifier transistor) SF. In addition, as illustrated in FIG. 3, the pixel unit 110 includes an electrode ME. Furthermore, as will be described later, the pixel unit 110 includes a transfer transistor TGM.

As illustrated in FIG. 2, the floating diffusion FD is located at a central part of the pixel unit 110. The photodiodes PD1 to PD4 are disposed at a distance around the floating diffusion FD. In addition, the photodiodes PD1 to PD4 are mutually spaced apart. The transfer transistors TGP0 to TGP4 are disposed between the photodiodes PD1 to PD4, on one hand, and the floating diffusion FD, on the other hand.

The reset transistor RST is disposed on one side of the photodiodes PD1 to 2D4 and floating diffusion FD, and the source follower amplifier transistor SF is disposed on the other side of the photodiodes PD1 to PD4 and floating diffusion FD.

The reset transistor RST is shared by two pixel units 110 which are juxtaposed in the column direction.

Specifically, the reset transistor RST is shared by eight photodiodes PD and two floating diffusions FD. Similarly, the source follower amplifier transistor SF is shared by two pixel units 110 which are juxtaposed in the column direction. Specifically, the source follower amplifier transistor SF is shared by eight photodiodes PD and two floating diffusions FD.

In the meantime, in the pixel unit 110 of this embodiment, one floating diffusion FD is shared by four photodiodes PD1 to PD4, but the embodiment is not limited to this example. For example, one floating diffusion FD may be shared by two photodiodes PD.

As illustrated in FIG. 3, the electrode ME is disposed above the floating diffusion FD, and overlaps the floating diffusion FD. The electrode ME overlaps parts of the photodiodes PD1 to PD4, but may not overlap parts of the photodiodes PD1 to PD4. Thereby, light-shielding by the electrode ME can be suppressed, and light can sufficiently be made incident on the photodiodes PD1 to PD4.

The electrodes ME, which are arranged in the row direction, are electrically connected to a common row select line, and the electrodes ME, which are arranged in the column direction, are electrically connected to a common column select line. Specifically, one row select line is disposed for one row, and one column select line is disposed for one column. The row select line is disposed, for example, in a manner to extend between the photodiodes PD1 and PD4 and between the photodiodes PD2 and PD3. On the other hand, the column select line is disposed, for example, in a manner to extend between the photodiodes PD1 and PD2 and between the photodiodes PD3 and PD4. In other words, the row select line and column select line do not overlap the photodiodes PD1 to PD4. Thereby, without light-shielding by the row select line and column select line, light can sufficiently be made incident on the photodiodes PD1 to PD4.

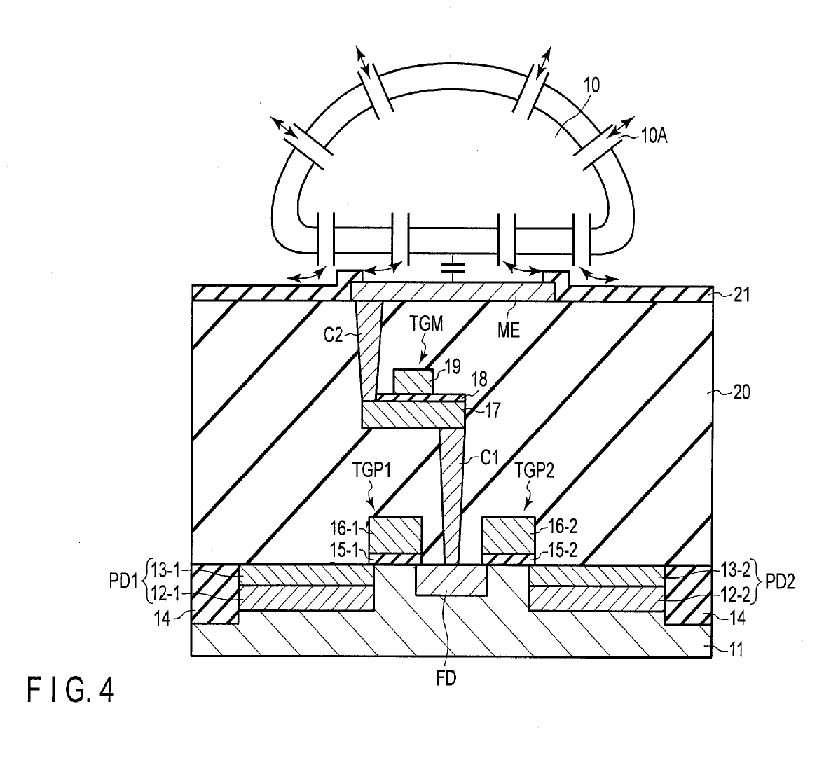

FIG. 4 is a cross-sectional view taken along line A-A in FIG. 3, FIG. 4 illustrating the pixel unit 110 of the sensing device according to the first embodiment.

As illustrated in FIG. 4, the photodiode PD1 is disposed on the surface of the semiconductor substrate 11. The photodiode PD1 is composed of an N-type diffusion layer 12-1 and a P-type diffusion layer 13-1. The P-type diffusion layer 13-1 is disposed on the surface of the semiconductor substrate 11, and the N-type diffusion layer 12-1 is disposed in contact with a lower portion of the P-type diffusion layer 13-1. Similarly, the photodiode PD2 is disposed on the surface of the semiconductor substrate 11, and is composed of an N-type diffusion layer 12-2 and a P-type diffusion layer 13-2. In addition, an insulation layer 14 is disposed as an STI (Shallow Trench Isolation) around the photodiodes PD1 and PD2.

The floating diffusion FD is disposed on the surface of the semiconductor substrate 11 and between the photodiodes PD1 and PD2.

The transfer transistor TGP1 is disposed between the photodiode PD1 and floating diffusion FD. The transfer transistor TGP1 is composed of a gate insulation layer 15-1 and a gate electrode 16-1, which are disposed in order on the semiconductor substrate 11. The transfer transistor TGP2 is disposed between the photodiode PD2 and floating diffusion FD. The transfer transistor TGP2 is composed of a gate insulation layer 15-2 and a gate electrode 16-2, which are disposed in order on the semiconductor substrate 11.

A contact C1 is disposed on the floating diffusion FD, and an oxide semiconductor layer 17 is disposed on the contact C1. The oxide semiconductor layer 17 is composed of a transparent semiconductor such as InGaZnO, ZnO, or In₂O₃.

The transfer transistor TGM is composed of a gate insulation layer 18 and a gate electrode 19, which are disposed on the oxide semiconductor layer 17. The gate electrode 19 is composed of a transparent metal such as ITO (indium tin oxide). The gate insulation layer 18 may be disposed on the entire surface of the oxide semiconductor layer 17, or may be disposed on a part of the oxide semiconductor layer 17.

A contact C2 is disposed on the oxide semiconductor layer 17. In addition, an interlayer insulation layer 20 is disposed in a manner to cover the photodiodes PD, floating diffusion FD, transfer transistors TGP, and transfer transistor TGM. The upper surface of the contact C2 is on a level with the upper surface of the interlayer insulation layer 20.

The electrode ME is disposed on the contact C2 and interlayer insulation layer 20. In addition, the electrode ME is disposed in a manner to overlap above the transfer transistor TGM. A passivation layer 21 is disposed on the interlayer insulation layer 20 and electrode ME. The passivation layer 21 includes an opening portion at a part of the electrode ME, and the upper surface of the electrode ME is exposed via this opening portion.

In the above configuration, a cell 10 is cultured directly on the passivation layer 21 and electrode ME, which have biocompatibility. The cell 10 includes ion channels 10A for transmitting/receiving ions. Although not illustrated, the cell 10 includes an axon, if the cell 10 is a nerve cell.

By capacitive coupling with the cell 10, the electrode ME senses a potential of the cell 10 and detects a potential signal. In addition, the photodiode PD generates an optical signal from incident light. This incident light may be, for example, light emitted from the cell 10 on the passivation layer 21 and electrode ME corresponding to light radiated from above. The light emitted from the cell 10 includes, for example, light such as fluorescence or self-luminous light, which the biotissue itself emits. Besides, light, which passes through the biotissue, may also be used. Moreover, a shadow of the biotissue may also be sensed by using light passing by the periphery of the biotissue. Specifically, the photodiode PD performs so-called “contact imaging”, which acquires an optical image of an observation target that is in contact with the passivation layer 21 and electrode ME. In this manner, in this embodiment, the potential (potential two-dimensional image) and the optical image of the cell 10 can be observed at the same time.

In the meantime, by the electrode ME, not only the potential but also various chemical parameters, such as pH, can be detected.

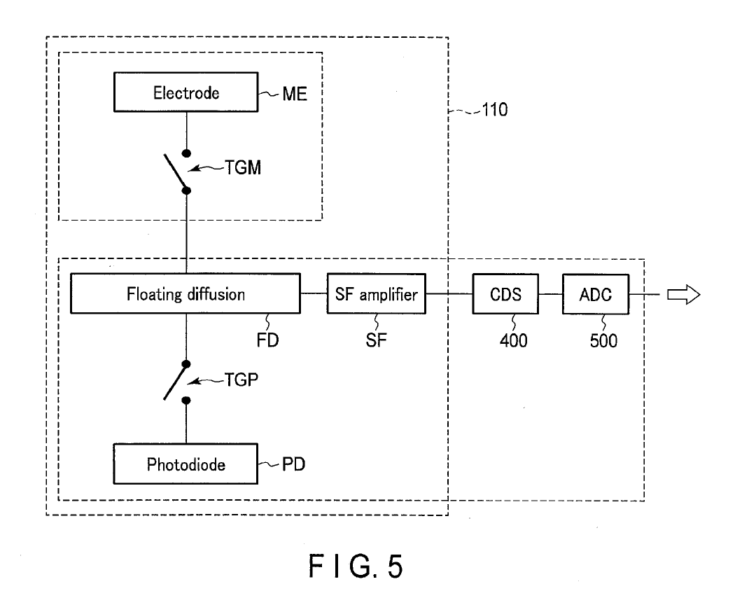

FIG. 5 is a block diagram illustrating an electrical connection relation of the pixel unit 110 according to the first embodiment. Here, unless particularly restricted, the term “connection” includes not only a case of a direct connection, but also a case of a connection with intervention of an arbitrary element.

As illustrated in FIG. 5, the photodiode PD is electrically connected to the floating diffusion FD via the transfer transistor TGP. The transfer transistor TGP transfers an optical signal, which was generated by the photodiode PD, to the floating diffusion FD. After storing a charge based on the optical signal from the transfer transistor TGP, the floating diffusion FD transfers the optical signal to the source follower amplifier SF. The source follower amplifier SF amplifies the optical signal from the floating diffusion FD, and transfers the amplified optical signal to the CDS 400 and ADC 500. Thereby, an optical image of the cell is observed.

On the other hand, the electrode ME is electrically connected to the floating diffusion FD via the transfer transistor TGM. The transfer transistor TGM transfers a potential signal, which was detected by the electrode ME, to the floating diffusion FD. After storing a charge based on the potential signal from the transfer transistor TGM, the floating diffusion FD transfers the potential signal to the source follower amplifier SF. The source follower amplifier SF amplifies the potential signal from the floating diffusion FD, and transfers the amplified potential signal to the CDS 400 and ADC 500. Thereby, the potential of the cell is observed.

Here, the photodiode PD, transfer transistor TGP, floating diffusion FD, source follower amplifier SF, CDS 400 and ADC 500 are disposed on the semiconductor substrate 11. In short, these are a so-called FEOL (Front End Of Line). On the other hand, the electrode ME and transfer transistor TGM are disposed on the wiring layer above the semiconductor substrate 11. In short, these are a so-called BEOL (Back End Of Line).

In this manner, in this embodiment, the optical signal, which was generated by the photodiode PD, and the potential signal, which was detected by the electrode ME are read by the common floating diffusion FD, source follower amplifier SF and read circuit (CDS 400 and ADC 500). The read of these signals is executed by switching on/off the transfer transistor TOP and transfer transistor TGM.

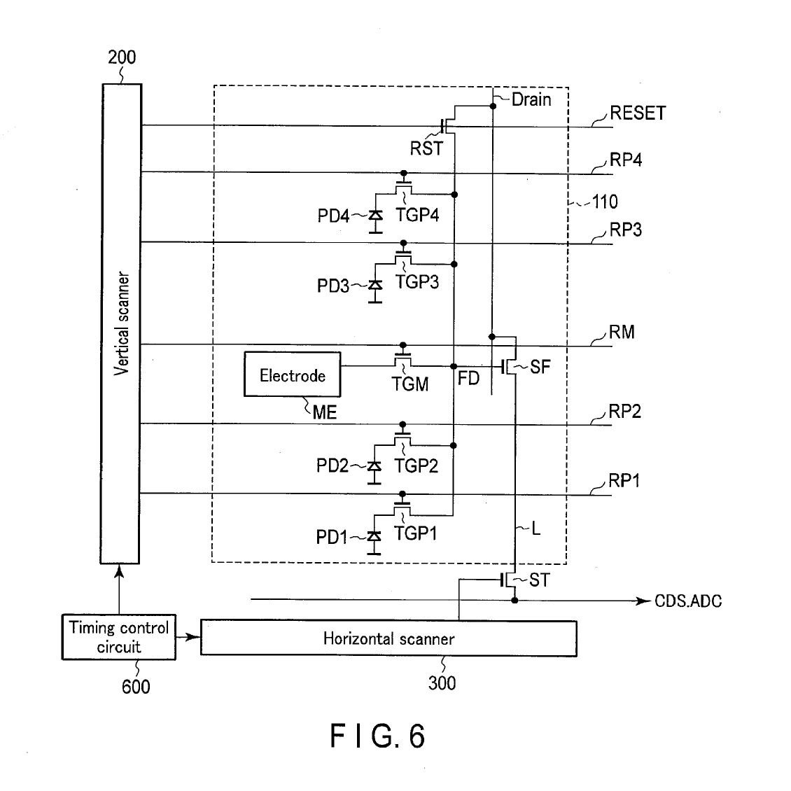

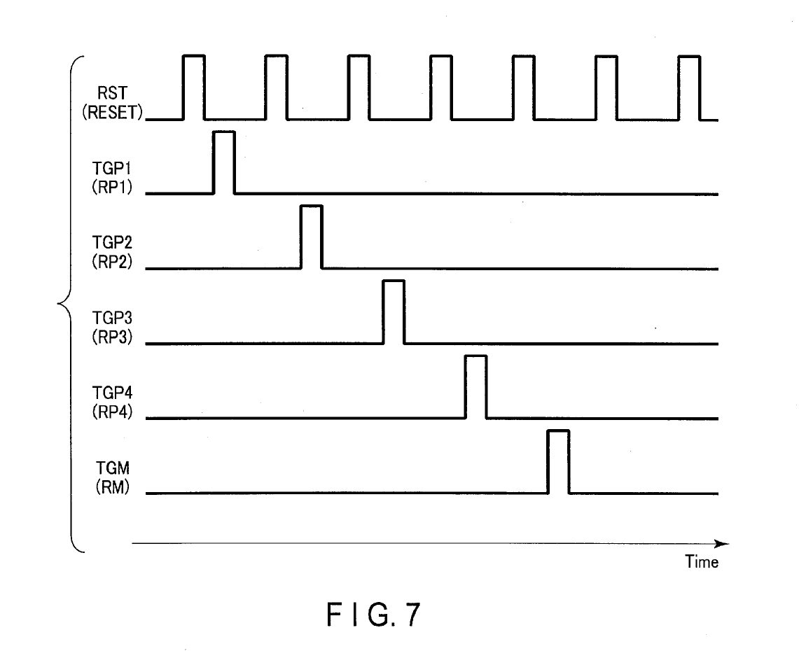

FIG. 6 is a circuit diagram illustrating, in greater detail, the electrical connection relation of the pixel unit 110 in the sensing device according to the first embodiment. FIG. 7 is a timing chart illustrating voltages of respective signal lines in the sensing device according to the first embodiment. FIG. 7 illustrates, in particular, the voltages of row select lines which are controlled by the vertical scanner 200.

In the meantime, a first terminal of a transistor, in this context, means one of the source and drain, and a second terminal of the transistor means the other of the source and drain. In addition, a control terminal means the gate.

As illustrated in FIG. 6, as described above, the pixel unit 110 includes the photodiodes PD1 to PD4, transfer transistors TGP1 to TGP4, and TGM, floating diffusion FD, reset transistor RST, source follower amplifier transistor SF, and electrode ME.

The anode of the photodiode PD1 is grounded, and the cathode thereof is connected to a first terminal of the transfer transistor TGP1. In addition, the anode of the photodiode PD2 is grounded, and the cathode thereof is connected to a first terminal of the transfer transistor TGP2. Further, the anode of the photodiode PD3 is grounded, and the cathode thereof is connected to a first terminal of the transfer transistor TGP3. Besides, the anode of the photodiode PD4 is grounded, and the cathode thereof is connected to a first terminal of the transfer transistor TGP4.

The gates (control terminals) of the transfer transistors TGP1 to TGP4 are connected to read signal lines (row select lines) RP1 to RP4, respectively, and read signals are supplied from the vertical scanner 200 to the gates (control terminals) of the transfer transistors TGP1 to TGP4. Second terminals of the transfer transistors TGP1 to TGP4 are commonly connected to the floating diffusion FD. In addition, the floating diffusion FD is connected to the gate (input terminal) of the source follower amplifier transistor SF.

The electrode ME is connected to a first terminal of the transfer transistor TGM. The gate of the transfer transistor TGM is connected to a read signal line (row select line) RM, and a read signal is supplied from the vertical scanner 200 to the gate of the transfer transistor TGM. A second terminal of the transfer transistor TGM is connected to the floating diffusion FD.

In addition, the floating diffusion FD is connected to a first terminal of the reset transistor RST. The gate of the reset transistor RST is connected to a reset signal line (row select line) RESET, and a reset signal is supplied from the vertical scanner 200 to the gate of the reset transistor RST. Furthermore, a second terminal of the reset transistor RST is connected to a voltage supply line (Drain).

A first terminal of the source follower amplifier transistor SF is connected to the voltage supply line (Drain). In addition, a second terminal of the source follower amplifier transistor SF is connected to a first terminal of a select transistor ST via a column select line L.

The gate of the select transistor ST is connected to the horizontal scanner 300, and a read signal is supplied from the horizontal scanner 300 to the gate of the select transistor ST. A second terminal of the select transistor ST is connected to the CDS 400 and ADC 500.

The horizontal scanner 300 and vertical scanner 200 are timing-controlled by a timing generation circuit 600. Specifically, the horizontal scanner 300 supplies a column select pulse to the gate of the select transistor ST in accordance with the timing control of the timing generation circuit 600. The vertical scanner 200 supplies row select pulses to the row select lines RP1 to RP4, RM and RESET in accordance with the timing control of the timing generation circuit 600.

To be more specific, as illustrated in FIG. 7, the vertical scanner 200 first supplies a row select pulse to the gate (row select line RESET) of the reset transistor RST. Thereby, the reset transistor RST is turned on, and the floating diffusion FD is reset. Next, the vertical scanner 200 supplies a row select pulse to the gate (row select line RP1) of the transfer transistor TGP1. Thereby, the transfer transistor TGP1 is turned on, and an optical signal is transferred from the photodiode PD1 to the floating diffusion FD and is stored as a charge. The charge stored in the floating diffusion FD is amplified by the source follower amplifier transistor SF, and then read out to the CDS 400 and ADC 500. Thereby, an optical image by the optical signal from the photodiode PD1 is acquired. Thereafter, the vertical scanner 200 supplies a row select pulse to the gate of the reset transistor RST, and resets the floating diffusion FD. Thereafter, similarly, optical images of the cell by the optical signals from the photodiodes PD2 to PD4 are observed.

Next, the vertical scanner 200 supplies a row select pulse to the gate (row select line RM) of the transfer transistor TGM. Thereby, the transfer transistor TGM is turned on, and a potential signal is transferred from the electrode ME to the floating diffusion FD and is stored as a charge. The charge stored in the floating diffusion FD is amplified by the source follower amplifier transistor SF, and then read out to the CDS 400 and ADC 500. Thereby, the potential of the cell by the potential signal from the electrode ME is observed.

### Advantageous Effects of the First Embodiment

According to the first embodiment, the pixel unit 110 includes the photodiodes PD disposed on the semiconductor substrate 11, and the electrode ME disposed above the photodiodes PD. The electrode ME is connected to the floating diffusion FD via the transfer transistor TGM, and the photodiodes PD are connected to the floating diffusion FD via the transfer transistors TGP. By switching on/off the transfer transistor TGM and transfer transistors TGP, the potential and optical image of the biotissue can be observed at the same time in time-division.

In addition, the transfer transistor TGM selects the corresponding electrode ME, and transfers the potential signal of this electrode ME. By disposing this transfer transistor TGM, the wirings for selecting any one of the plural electrodes ME, which are arranged in a matrix, can be configured such that one line is disposed for one row and one line is disposed for one column, and the number of wirings can be reduced. Accordingly, light-shielding by wirings can be suppressed, and the sensitivity of an optical image by the photodiode PD can be enhanced. In addition, the number of electrodes ME, which was difficult to increase due to an increase in the number of wirings, can be increased, and the resolution of potential observation can be enhanced.

Furthermore, the electrode ME and photodiode PD share the floating diffusion FD, source follower amplifier SF and read circuit (CDS 400 and ADC 500). Thereby, an increase in chip size can be suppressed, compared to the case of using different read circuits for the electrode ME and photodiode PD.

### Second Embodiment

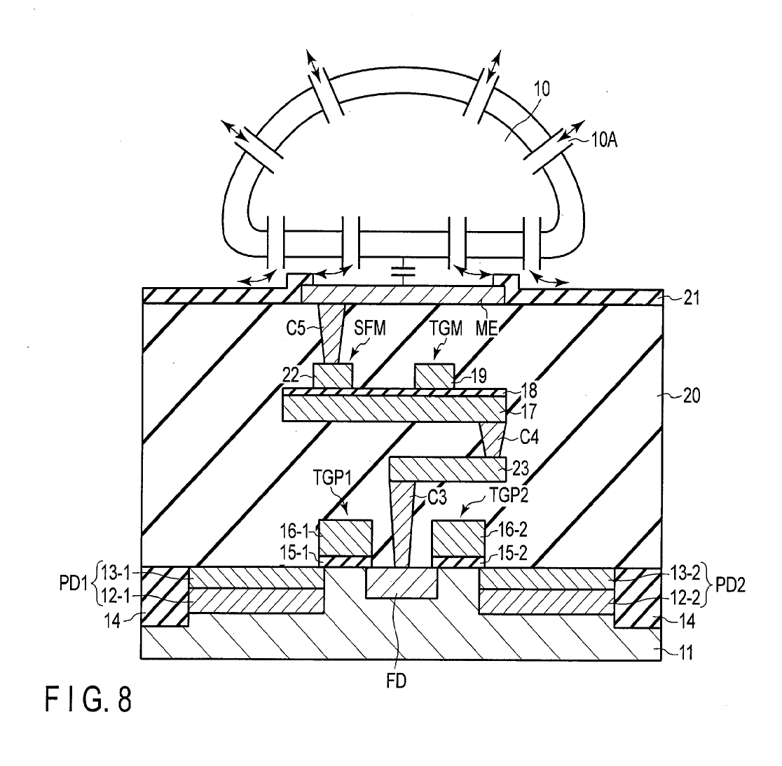

Referring to FIGS. 8, 9, 10, 11, and 12, a sensing device according to a second embodiment will be described below.

In the second embodiment, a source follower amplifier SFM for the electrode ME is disposed. Thereby, even when the magnitude of the potential signal from the electrode ME and the magnitude of the optical signal from the photodiode PD are different, these magnitudes can be substantially equalized. As a result, the read circuit can be shared by the electrode ME and photodiode PD, and the respective signals can be read.

Next, the second embodiment is described in detail. Incidentally, in the second embodiment, a description of the same points as in the first embodiment is omitted, and different points are mainly described.

### Configuration and Operation in the Second Embodiment

FIG. 8 is a cross-sectional view illustrating a pixel unit 110 of the sensing device according to the second embodiment.

As illustrated in FIG. 8, the second embodiment differs from the first embodiment in that a source follower amplifier (source follower amplifier transistor) SFM for the electrode ME is disposed.

A contact C3 is disposed on the floating diffusion FD. A wiring layer 23 is disposed on the contact C3. The wiring layer 23 is composed of a transparent metal such as ITO (indium tin oxide). A contact C4 is disposed on the wiring layer 23. An oxide semiconductor layer 17 is disposed on the contact C4.

A transfer transistor TGM is composed of a gate insulation layer 18 and a gate electrode 19, which are disposed on the oxide semiconductor layer 17.

The source follower amplifier transistor SFM is composed of the gate insulation layer 18 and a gate electrode 22, which are disposed on the oxide semiconductor layer 17. The gate electrode 22 is composed of a transparent metal such as ITO (indium tin oxide).

A contact C5 is disposed on the gate electrode 22. The electrode ME is disposed on the contact C5.

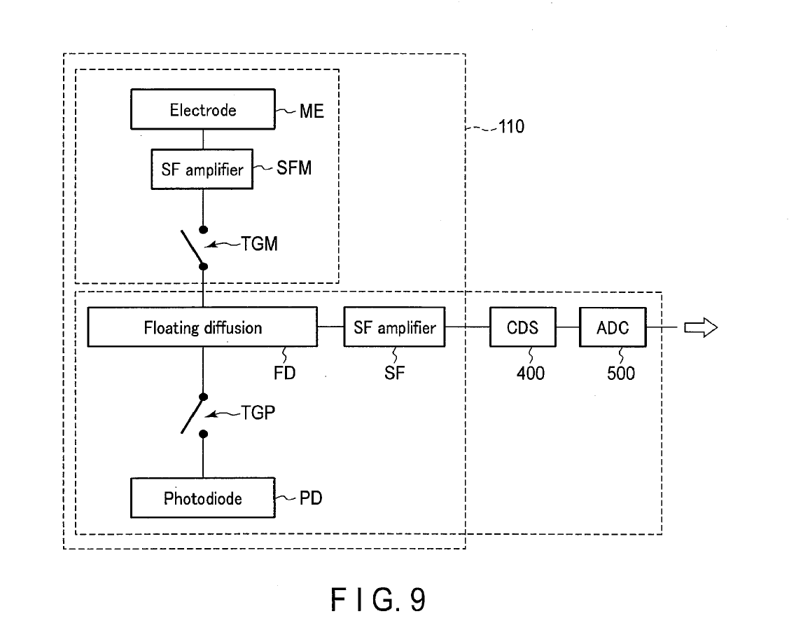

FIG. 9 is a block diagram illustrating an electrical connection relation of the pixel unit 110 according to the second embodiment.

As illustrated in FIG. 9, the electrode ME transfers a potential signal to the source follower amplifier SFM. The source follower amplifier SFM amplifies the potential signal from the electrode ME, and transfers the amplified potential signal to the transfer transistor TGM. At this time, the source follower amplifier SFM amplifies the potential signal at a different amplification factor from the source follower amplifier SF. The transfer transistor TGM transfers the potential signal from the source follower amplifier SFM to the floating diffusion FD. After storing a charge based on the potential signal from the transfer transistor TGM, the floating diffusion FD transfers the potential signal to the source follower amplifier SF. The source follower amplifier SF amplifies the potential signal from the floating diffusion FD, and transfers the amplified potential signal to the CDS 400 and ADC 500. Thereby, the potential of the cell is observed.

Here, the source follower amplifier SFM is disposed on the wiring layer above the semiconductor substrate 11. Specifically, the source follower amplifier SFM is a so-called BEOL (Back End Of Line).

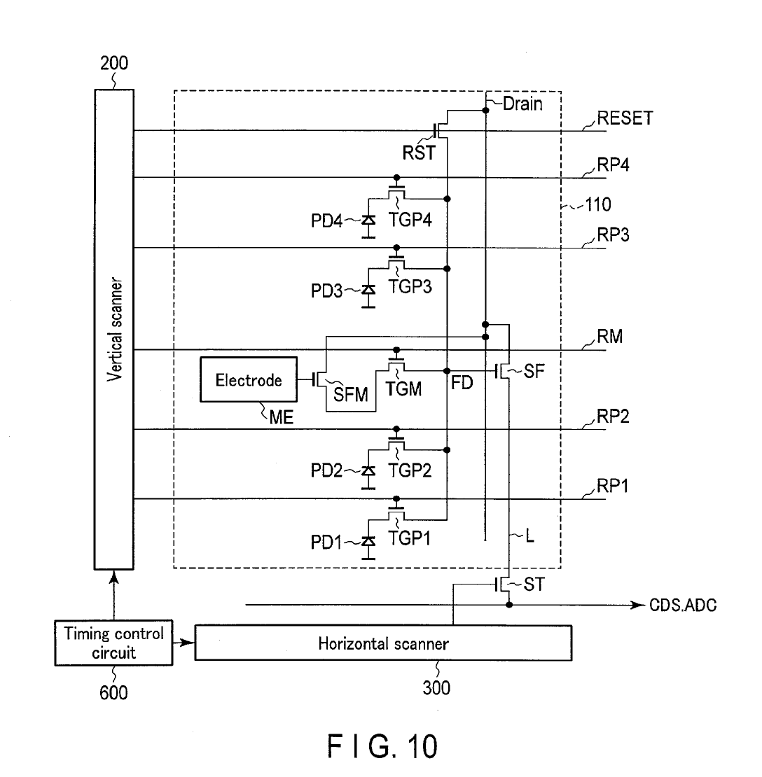

FIG. 10 is a circuit diagram illustrating, in greater detail, the electrical connection relation of the pixel unit 110 in the sensing device according to the second embodiment.

As illustrated in FIG. 10, the pixel unit 110 includes the photodiodes PD1 to PD4, transfer transistors TGP1 to TGP4, floating diffusion FD, reset transistor RST, and source follower amplifier transistors SF and SFM.

The electrode ME is connected to the gate (input terminal) of the source follower amplifier transistor SFM. A first terminal of the source follower amplifier transistor SFM is connected to the voltage supply line Drain, and a second terminal thereof is connected to a first terminal of the transfer transistor TGM. The gate of the transfer transistor TGM is connected to the read sinal line (row select line) RM, and a read signal is supplied from the vertical scanner 200 to the gate of the transfer transistor TGM. A second terminal of the transfer transistor TGM is connected to the floating diffusion FD.

### Advantageous Effects of the Second Embodiment

According to the second embodiment, the source follower amplifier SFM for the electrode ME is disposed. The potential signal of the electrode ME is amplified by the source follower amplifier SFM, and then the amplified potential signal is transferred to the read circuit (CDS 400 and ADC 500) via the floating diffusion FD and source follower amplifier SF. The source follower amplifier SFM amplifies the potential signal at a different amplification factor from the source follower amplifier SF. Thereby, even when the magnitude of the potential signal from the electrode ME and the magnitude of the optical signal from the photodiode PD are different (in particular, when the potential signal is smaller than the optical signal), these magnitudes can be substantially equalized. As a result, the read circuit can be shared by the electrode ME and photodiode PD, and the respective signals can be read.

In addition, after amplified by the source follower amplifier SFM, the potential signal is stored by the floating diffusion FD, and is further amplified by the source follower amplifier SF. Thereby, even when the potential signal of the electrode ME is very small and the amplification by the source follower amplifier SFM is insufficient, the potential signal from the electrode ME can be amplified up to an adequate level for read.

In the meantime, ions, such as Na⁺, K⁺ and Ca⁺, are transmitted/received through the ion channels 10A in the cell 10. As described above, in the second embodiment, a very small potential variation of the cell 10 can be detected. Thus, by an ion sensitive film (valinomycin, phosphotyrosine, acetylcholine, lactic acid, or glucose) being disposed on some of the plural electrodes ME, a minute potential variation due to ion transmission/reception can be detected. Thereby, a propagation reaction of ions can be acquired as a two-dimensional distribution image.

### Modification of the Second Embodiment

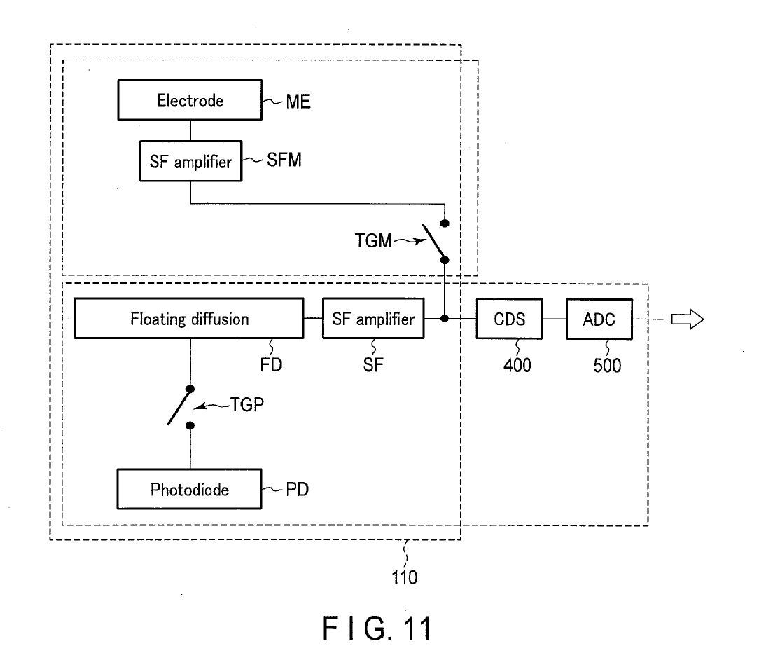

FIG. 11 is a block diagram illustrating an electrical connection relation of a pixel unit 110 according to a modification of the second embodiment.

As illustrated in FIG. 11, the electrode ME transfers a potential signal to the source follower amplifier SFM. The source follower amplifier SFM amplifies the potential signal from the electrode ME, and transfers the amplified potential signal to the transfer transistor TGM. At this time, the source follower amplifier SFM amplifies the potential signal at a different amplification factor from the source follower amplifier SF. The transfer transistor TGM transfers the potential signal from the source follower amplifier SFM to the CDS 400 and ADC 500. Thereby, the potential of the cell is observed.

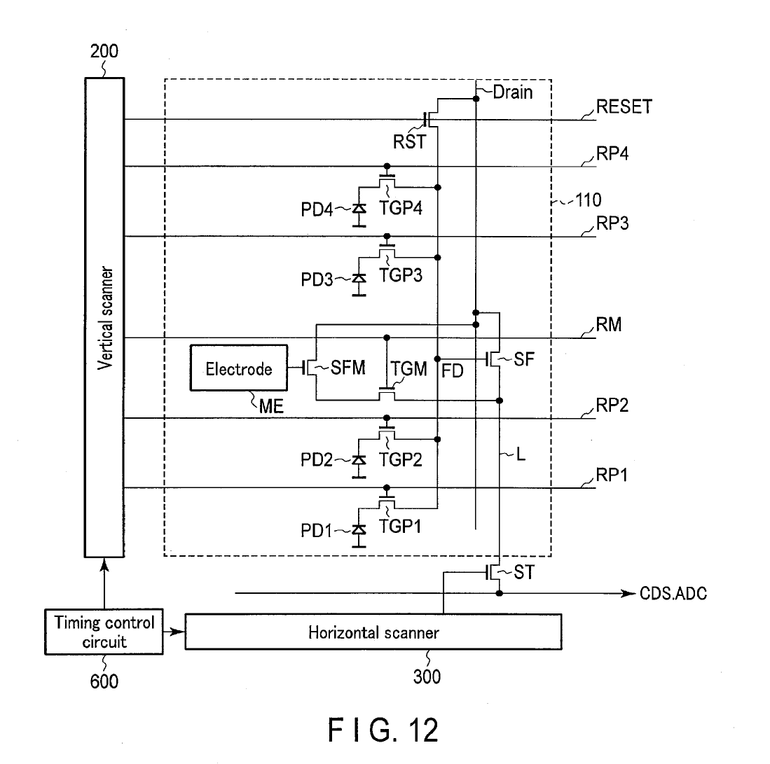

FIG. 12 is a circuit diagram illustrating, in greater detail, the electrical connection relation of the pixel unit 110 in the sensing device according to the modification of the second embodiment.

As illustrated in FIG. 12, the pixel unit 110 includes the photodiodes PD1 to PD4, transfer transistors TGP1 to TGP4, floating diffusion FD, reset transistor RST, and source follower amplifier transistors SF and SFM.

The electrode ME is connected to the gate (input terminal) of the source follower amplifier transistor SFM. A first terminal of the source follower amplifier transistor SFM is connected to the voltage supply line Drain, and a second terminal thereof is connected to a first terminal of the transfer transistor TGM. The gate of the transfer transistor TGM is connected to the read signal line (row select line), and a read signal is supplied from the vertical scanner 200 to the gate of the transfer transistor TGM. A second terminal of the transfer transistor TGM is connected to a first terminal of the select transistor ST via the column select line.

As illustrated in the above modification, when the potential signal of the electrode ME is sufficiently amplified by the source follower amplifier transistor SFM, the potential signal may be transferred to the read circuit (CDS 400 and ADC 500) without intervention of the floating diffusion FD and source follower amplifier SF. Thereby, the read speed of the potential signal can be increased, compared to the second embodiment.

### Third Embodiment

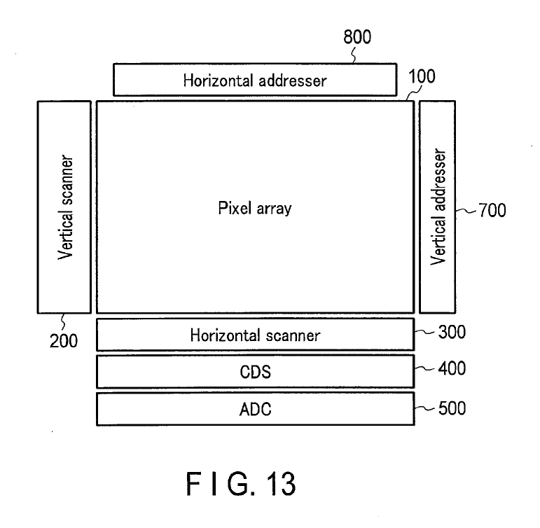

Referring to FIG. 13 to FIG. 16, a sensing device according to a third embodiment will be described below.

In the third embodiment, a voltage supply unit 120 is disposed. Thereby, potential stimulation can be applied to an arbitrary cell 10 via the electrode ME. In addition, optical images of a local reaction of the cell 10 by the potential stimulation and a propagation of a reaction between cells 10 can be obtained.

Next, the third embodiment is described in detail. Incidentally, in the third embodiment, a description of the same points as in the first embodiment is omitted, and different points are mainly described.

### Configuration and Operation in the Third Embodiment

FIG. 13 is a block diagram illustrating the entire configuration of the sensing device according to the third embodiment.

As illustrated in FIG. 13, the sensing device includes a pixel array 100, a vertical scanner 200, a horizontal scanner 300, a CDS 400, an ADC 500, a vertical addresser 700, and a horizontal addresser 800.

The pixel array 100 generates an optical signal, and generates a potential signal. In addition, the pixel array 100 applies potential stimulation to an arbitrary biotissue. The vertical addresser 700 selects a row of pixel units 110, and the horizontal addresser 800 selects a column of pixel units 110. A voltage is applied to the electrode ME of a selected pixel unit 110, and potential stimulation is applied to a cell 10 located at this electrode ME.

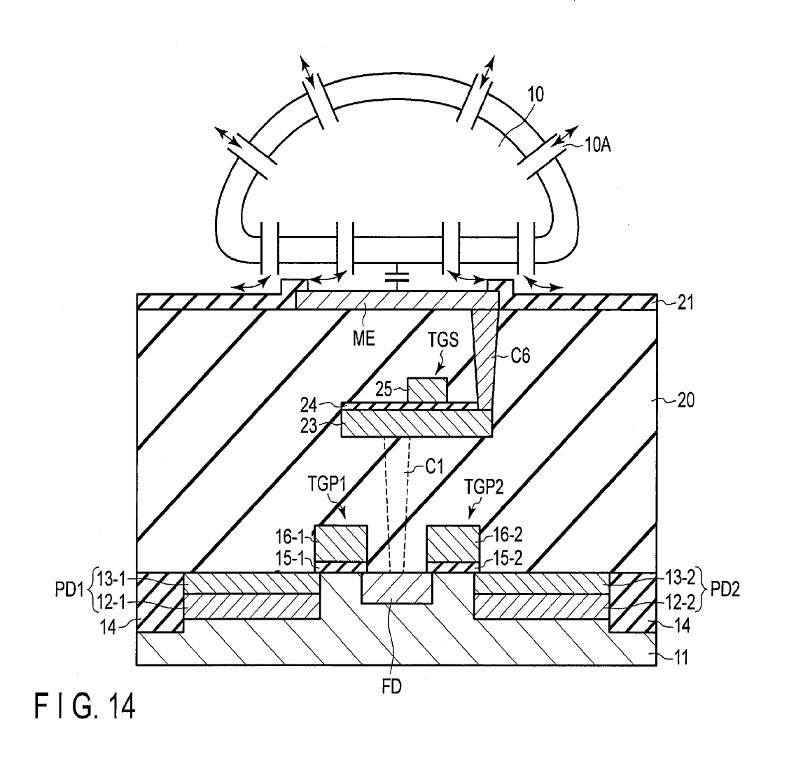

FIG. 14 is a cross-sectional view illustrating the pixel unit 110 of the sensing device according to the third embodiment. The cross section shown in FIG. 14 is a cross section which is different from the cross section shown in FIG. 4.

As illustrated in FIG. 14, an oxide semiconductor layer 23 is disposed in the same layer as the oxide semiconductor layer 17. The oxide semiconductor layer 23 is composed of a transparent semiconductor such as InGaZnO, ZnO, or In₂O₃.

The transfer transistor TGS is composed of a gate insulation layer 24 and a gate electrode 25, which are disposed on the oxide semiconductor layer 23. Specifically, the transfer transistor TGS is formed in the same layer as the transfer transistor TGM. The gate electrode 25 is composed of a transparent metal such as ITO (indium tin oxide). The gate insulation layer 24 may be disposed on the entire surface of the oxide semiconductor layer 23, or may be disposed on a part of the oxide semiconductor layer 23.

A contact C6 is disposed on the oxide semiconductor layer 23. The upper surface of the contact C6 is on a level with the upper surface of the interlayer insulation layer 20. The electrode ME is disposed on the contact C6 and interlayer insulation layer 20.

By capacitive coupling with the cell 10, the electrode ME senses a potential of the cell 10 and detects a potential signal. In addition, the electrode ME applies potential stimulation to the cell 10, based on a voltage which is transferred from the voltage supply unit 120 (to be described later) via the transfer transistor TGS.

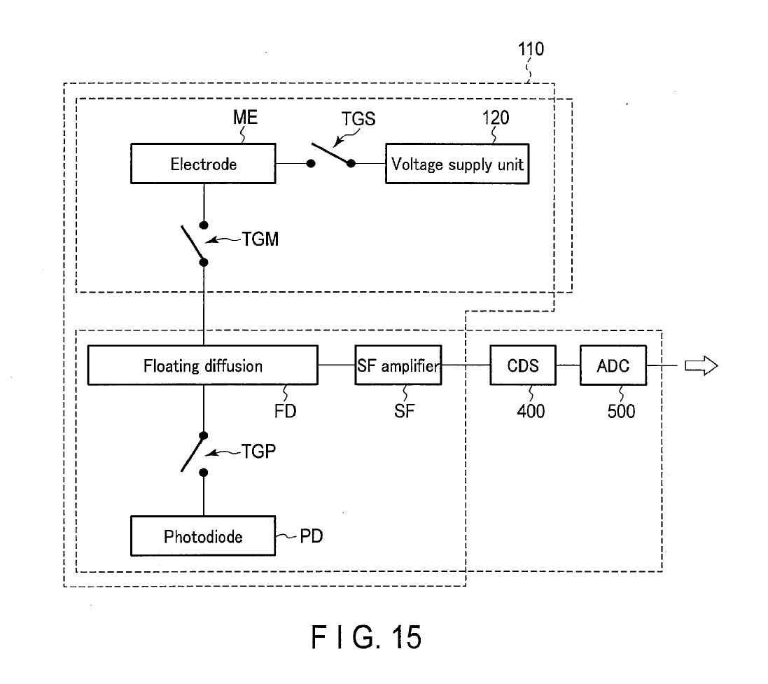

FIG. 15 is a block diagram illustrating an electrical connection relation of the pixel unit 110 according to the third embodiment.

As illustrated in FIG. 15, the electrode ME is electrically connected to the voltage supply unit 120 via the transfer transistor TGS. The transfer transistor TGS transfers a voltage from the voltage supply unit 120 to the electrode ME. Based on the voltage transferred from the transfer transistor TGS, the electrode ME applies potential stimulation to the cell 10. At the same time, by the optical signal being transferred from the photodiode PD, it is possible to obtain an optical image of a local reaction of the cell 10 by the potential stimulation and an optical image of a propagation of a reaction between cells 10 by the potential stimulation.

Here, the voltage supply unit 120 and transfer transistor TGS are disposed on the wiring layer above the semiconductor substrate 11. Specifically, the voltage supply unit 120 and transfer transistor TGS are a so-called BEOL (Back End Of Line).

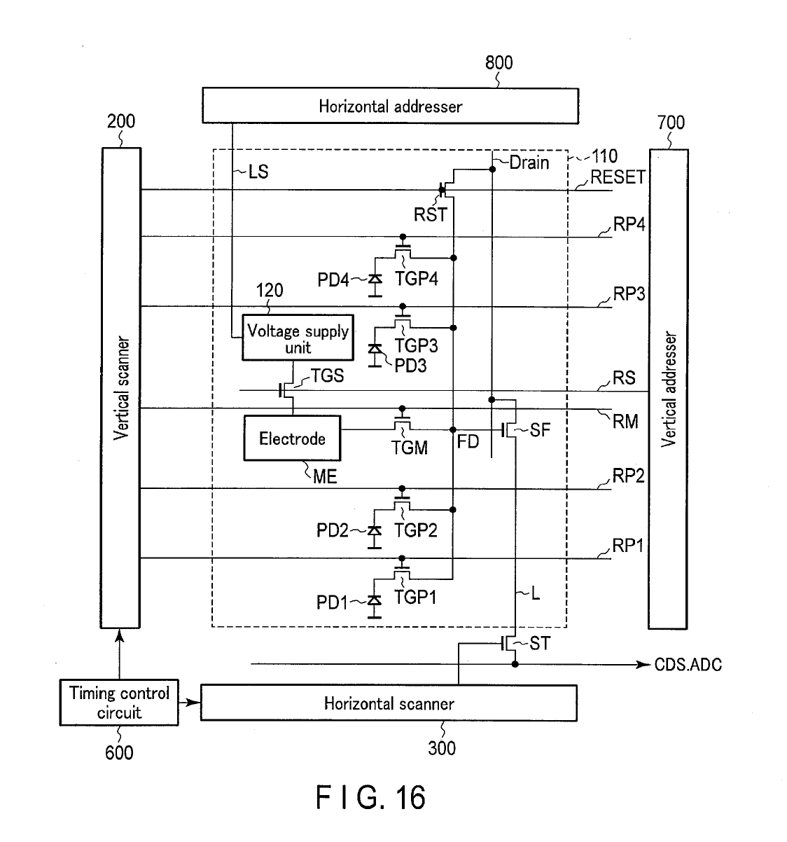

FIG. 16 is a circuit diagram illustrating, in greater detail, the electrical connection relation of the pixel unit 110 in the sensing device according to the third embodiment.

As illustrated in FIG. 16, the pixel unit 110 includes the photodiodes PD1 to PD4, transfer transistors TGP1 to TGP4, TGM and TGS, floating diffusion FD, reset transistor RST, source follower amplifier transistor SF, electrode ME, and voltage supply unit 120.

The electrode ME is connected to a first terminal of the transfer transistor TGS. The gate of the transfer transistor TGS is connected to a voltage supply line (row select line) RS, and a voltage supply signal is supplied from the vertical addresser 700 to the gate of the transfer transistor TGS. A second terminal of the transfer transistor TGS is connected to the voltage supply unit 120. The voltage supply unit 120 is connected to a voltage supply line (column select line) LS, and a voltage supply signal is supplied from the horizontal addresser 800 to the voltage supply unit 120. The voltage supply unit 120 charges a voltage in accordance with the voltage supply signal from the horizontal addresser 800.

In this embodiment, a voltage (potential stimulation) is applied to the electrode ME of a predetermined pixel unit 110 by the selection of the vertical addresser 700 and horizontal addresser 800. To be more specific, the voltage supply unit 120 is charged by the voltage supply signal from the horizontal addresser 800, and the transfer transistor TGS is turned on by the voltage supply signal from the vertical addresser 700. Thereby, a voltage (potential stimulation) is applied to the electrode ME of the predetermined pixel unit 110. At the same time, the optical image of the reaction of the cell 10 by the potential stimulation can be obtained by turn-on of the transfer transistor TGP.

### Advantageous Effects of the Third Embodiment

According to the third embodiment, the voltage supply unit 120 is disposed. The voltage supply unit 120 supplies a voltage to the electrode ME. Thereby, potential stimulation can be applied to an arbitrary cell 10 via the electrode ME. As a result, optical images of a local reaction of the cell 10 by the potential stimulation and a propagation of a reaction between cells 10 can be obtained.

Furthermore, the voltage supply unit 120 is selected by the transfer transistor TGS, and potential stimulation is transferred. Specifically, the wirings for selecting the voltage supply unit 120 can be configured such that one line is disposed for one row and one line is disposed for one column, and the number of wirings can be reduced. Accordingly, light-shielding by wirings can be suppressed, and the sensitivity of the photodiode PD can be enhanced.

Incidentally, the above-described third embodiment and the second embodiment can be combined.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A sensing device comprising:
a photodiode;
a first transistor including a first terminal, a second terminal and a control terminal, the first terminal being connected to the photodiode;
an electrode configured to detect a potential of the measurement target;
a second transistor including a third terminal, a fourth terminal and a control terminal, the third terminal being connected to the electrode; and
a charge storage connected to the second terminal of the first transistor and to the fourth terminal of the second transistor.

2. The device of claim 1, further comprising a first amplifier including an input terminal connected to the charge storage.

3. The device of claim 1, further comprising a read circuit connected to the charge storage.

4. The device of claim 1, wherein the first transistor is disposed on a semiconductor substrate, and
the second transistor is disposed on a semiconductor layer which is disposed above the semiconductor substrate.

5. The device of claim 4, wherein the photodiode is disposed on the semiconductor substrate, and
the electrode is disposed above the semiconductor layer.

6. The device of claim 1, further comprising:
a fifth terminal configured to supply a voltage; and
a third transistor including a sixth terminal, a seventh terminal and a control terminal, the sixth terminal being connected to the fifth terminal, and the seventh terminal being connected to the electrode,
wherein the electrode is configured to apply a potential to the measurement target, based on the voltage supplied via the fifth terminal.

7. The device of claim 6, wherein the first transistor is disposed on a semiconductor substrate,
the second transistor is disposed on a first semiconductor layer which is disposed above the semiconductor substrate, and
the third transistor is disposed on a second semiconductor layer which is disposed above the semiconductor substrate.

8. The device of claim 6, further comprising a control circuit configured to control the respective transistors,
wherein the control circuit is configured to turn on the third transistor, and to turn on the first transistor.

9. The device of claim 1, further comprising a control circuit configured to control the respective transistors,
wherein the control circuit is configured to alternately turn on the first transistor and the second transistor.

10. The device of claim 1, wherein the electrode is disposed above the photodiode and the electrode overlaps at least a part of the photodiode.

11. A sensing device comprising:
a photodiode;
a first transistor including a first terminal, a second terminal and a control terminal, the first terminal being connected to the photodiode;
an electrode configured to detect a potential of the measurement target;
a first amplifier including an input terminal and an output terminal, the input terminal being connected to the electrode;
a second transistor including a third terminal, a fourth terminal and a control terminal, the third terminal being connected to the output terminal of the first amplifier; and
a charge storage connected to the second terminal of the first transistor.

12. The device of claim 11, further comprising a second amplifier including an input terminal connected to the charge storage.

13. The device of claim 11, further comprising a read circuit connected to the charge storage and the fourth terminal of the second transistor.

14. The device of claim 11, wherein the first transistor is disposed on a semiconductor substrate, and
the second transistor is disposed on a semiconductor layer which is disposed above the semiconductor substrate.

15. The device of claim 14, wherein the photodiode is disposed on the semiconductor substrate, and
the electrode is disposed above the semiconductor layer.

16. The device of claim 11, further comprising:
a fifth terminal configured to supply a voltage; and
a third transistor including a sixth terminal, a seventh terminal and a control terminal, the sixth terminal being connected to the fifth terminal, and the seventh terminal being connected to the electrode,
wherein the electrode is configured to apply a potential to the measurement target, based on the voltage supplied via the fifth terminal.

17. The device of claim 16, wherein the first transistor is disposed on a semiconductor substrate,
the second transistor is disposed on a first semiconductor layer which is disposed above the semiconductor substrate, and
the third transistor is disposed on a second semiconductor layer which is disposed above the semiconductor substrate.

18. The device of claim 16, further comprising a control circuit configured to control the respective transistors,
wherein the control circuit is configured to turn on the third transistor, and to turn on the first transistor.

19. The device of claim 11, further comprising a control circuit configured to control the respective transistors,
wherein the control circuit is configured to alternately turn on the first transistor and the second transistor.

20. The device of claim 1, wherein the electrode is disposed above the photodiode and the electrode overlaps at least a part of the photodiode.
